(19) United States
(12) Patent Application Publication
(10) Pub. No.: US 2006/0154383 A1
(43) Pub. Date: Jul. 13, 2006

(54) Processing apparatus and processing method

(75) Inventors: Hiroshi Kannan, Tokyo (JP); Tadahiro Ishizaka, Yamanashi (JP); Yasuhiko Kojima, Yamanashi (JP); Yasuhiro Oshima, Yamanashi (JP); Takashi Shigeoka, Yamanashi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED

(21) Appl. No.: 10/526,019

(22) PCT Filed: Aug. 15, 2003
(86) PCT No.: PCT/JP03/10377

§ 371 Date: Jul. 25, 2005

(30) Foreign Application Priority Data
Aug. 30, 2002 (JP) 2002-253674

(51) Int. Cl. H01L 21/00; C23C 16/00

(52) U.S. Cl. 438/5; 118/715

(57) ABSTRACT

In a processing apparatus, a process gas including a source gas (TiCl₄, NH₃) and an inert gas (N₂) is supplied into a process chamber (2). A pressure meter (6) detects a pressure in the process chamber (2) so as to control an amount of flow of the process gas supplied to the process chamber (2) based on a result of the detection. A source gas is purged by the inert gas. By maintaining the amount of flow of the source gas constant and controlling the amount of flow of the inert gas, an amount of flow the entire process gas is controlled so as to maintain a pressure in the process chamber (2) constant. Since a time spent on evacuation of the source gas is reduced, a time for switching the source gas is reduced. Additionally, a temperature of a surface of a substrate during processing can be maintained constant.

### TECHNICAL FIELD

The present invention relates to processing apparatuses and, more particularly, to a processing apparatus and a processing method that perform a process on a substrate in a process chamber while supplying gas to the process chamber.

### BACKGROUND ART

As a method of processing a substrate of a semiconductor device, a method of processing the substrate by supplying a source gas and purge gas into a process chamber that is maintained at a predetermined degree of vacuum is common. For example, as a method of forming a high-quality thin film on a substrate by supplying process gas to the heated substrate under a reduced pressure, ALD (Atomic Layer Deposition) has attracted attention in recent years.

In ALD, a plurality of kinds of source gases are supplied to a substrate alternately under a pressure of about 200 Pa and caused to react with each other on the substrate that is heated at 400° C. to 500° C. so as to form a very thin film of a reaction product. In this regard, it is necessary to supply the plurality of kinds of source gases on an individual kind basis so that the source gasses do not react with each other before reaching the substrate. That is, after only one kind of gas is supplied to the substrate, the gas is completely evacuated, and, then, a different kind of source gas is supplied. This process is repeated so as to cause a thin film to grow to have a certain thickness.

In such a processing method of alternately supplying source gases, it is indispensable to switch the source gases at high speed so as to improve a throughput. In switching the source gases, a process is performed to supply a subsequent kind of source gas after completely evacuating one kind of source gas, which has been supplied. Therefore, in order to evacuate a source gas from a reaction chamber, it is effective in achieving high-speed evacuation to reduce an amount of the source gas remaining in the reaction chamber when supply of the source gas is stopped. That is, it is effective for an increase in processing speed to reduce the volume of the reaction chamber in which the source gas can remain.

Specifically, in order to specifically evacuate the remaining source out of the reaction chamber, it can be achieved by evacuating the source gas remaining in the reaction chamber by a vacuum pump or the like to reduce the pressure in the reaction chamber to a predetermined degree of vacuum. Here, the ultimate pressure P in the reaction chamber can be acquired by the following equation, where the ultimate pressure in the reaction chamber is P, the volume of the reaction chamber is V, an evacuation speed is S, a time is t.
P=P₀ exp{−(S/V)t}

It can be appreciated from the above equation, if the initial pressure and the ultimate pressure are constant, the time t can be reduced by increasing the evacuation speed S or deceasing the volume V. In order to enlarge the evacuation speed S, a high-speed, large capacity vacuum pump is needed, which gives influence to a manufacturing cost greatly. Therefore, it is desirable to reduce the capacity V of the reaction chamber.

The pressure in the process chamber at the time of processing is about 200 Pa, and it is efficient to evacuate the process gas from the process chamber using a dry pump since the gas is the range of a viscous flow. However, in the evacuation at the time of switching to the process gases, it is necessary to set the pressure inside the process chamber lower than 1 Pa, for example, 10⁻² to 10⁻³ Pa. With such a high degree of vacuum, the flow of gas is in a range of molecular flow, and it is inefficient to evacuate by a dry pump or is it not possible to achieve such a vacuum sorely by a dry pump. Therefore, when switching a source gases, it is necessary to use a turbomorecular pump together with a dry pump.

As mentioned above, when a turbomolecular pump is used for evacuation when switching process gas, it is necessary to enlarge the opening of the exhaust port connected to the process chamber. However, enlarging the opening of the exhaust port causes substantially enlarging the process chamber, and there is a problem in that a time required for evacuation is long.

Moreover, when evacuating a source gas at a high-vacuum level in a process chamber, it is necessary to wait for until a pressure inside the process chamber reaches a process pressure after the evacuation is completed. If the process pressure is relatively high pressure, the waiting time for pressure adjustment gives great influence to the process time, which causes the entire process time to become long.

Moreover, when evacuating gas until a high-vacuum is formed in a process chamber, since a source gas, which has been adsorbed onto an inner wall of the process chamber, is released, there is a problem in that the evacuation speed is limited depending on the source gas being released.

Further, although it is necessary to control an amount of the adsorbed source gas by setting the surface of the substrate at a constant temperature, the temperature of the surface of the substrate is changed if a pressure inside the process chamber changes at the time of switching the source gas. That is, the heating of the substrate is dependent on an amount of heat transmitted to the substrate through the process gas in the process chamber, which exists between the substrate and the support member supporting the substrate. When a pressure in the process chamber is high, the thermal conductivity of the process gas is high, which increases an amount heat to the substrate so that the temperature of the substrate becomes high. On the other hand, if a pressure in the process chamber becomes low, the thermal conductivity of the process gas is decreased, which caused the temperature of the substrate to become low. Therefore, when the pressure inside the process chamber changes greatly between the process pressure and the evacuation pressure, the temperature of the surface of the substrate fluctuates, which causes a problem in that an amount of the source gas to be adsorbed onto the substrate cannot be controlled accurately.

### DISCLOSURE OF THE INVENTION

It is a general object of the present invention to provide an improved and useful processing apparatus in which the above-mentioned problems are eliminated.

A more specific object of the present invention is to provide a processing apparatus and a processing method that can reduce a switching time of source gases by reducing a time spent on evacuation of the source gases, and that can maintain a temperature of a surface of a substrate during a process by performing supply and evacuation of the process gases at a constant pressure.

In order to achieve the above-mentioned objects, there is provided according to one aspect of the present invention a processing apparatus performing a process on a substrate while supplying a process gas including a source gas and an inert gas, comprising: a process chamber in which the substrate is accommodated; process gas supply means for supplying the process gas into the process chamber; exhaust means; pressure detecting means for detecting a pressure in the process chamber; and control means for controlling an amount of flow of the process gas supplied to the process chamber based on a result of detection of the pressure detecting means.

In the processing apparatus according to the present invention, the processing gas supply means may include source gas supply means for supplying a source gas and an inert gas supply means for supplying an inert gas, and the control means may control an amount of flow of the process gas to be supplied to the process chamber by controlling an amount of flow of the inert gas by controlling the inert gas supply means.

Additionally, the source gas supply means may supply a plurality of kinds of source gases alternately to the process chamber, and the inert gas supply means may continuously supply the inert gas to the process chamber. Further, the control means may control the amount of flow of the process gas so that a pressure in the process chamber is substantially constant. Additionally, the control means preferably control the amount of flow of the process gas so that a pressure in the process chamber falls within a range of ±10% of a predetermined pressure.

Additionally, there is provided according to another aspect of the present invention a processing method of applying a process to a substrate while supplying a process gas including a source gas and an inert gas, comprising: a first step of supplying a first source gas to a process chamber at a first predetermined amount of flow and simultaneously supplying an inert gas to the process chamber so as to maintain inside the process chamber at a predetermined process pressure; a second step of stopping supply of the first source gas and continuously supplying only the inert gas so as to maintain inside the process chamber at the predetermined process pressure; a third step of supplying a second source gas to the process chamber at a second predetermined amount of flow and simultaneously supplying the inert gas to the process chamber so as to maintain inside the process chamber at the predetermined process pressure; and a fourth step of stopping supply of the second source gas and continuously supplying only the inert gas so as to maintain inside the process chamber at the predetermined process pressure, wherein the process is applied to the substrate by repeatedly performing the first step to the fourth step.

In the above-mentioned processing method, the first source gas may be TiCl₄, the second source gas may be NH₃ and the inert gas may be N₂. Additionally, the first predetermined amount of flow may be 1 to 50 sccm, the second predetermined amount of flow may be 10 to 1000 sccm and the predetermined process pressure may be 1 to 400 Pa. Additionally, the allowable range of fluctuation of the predetermined process pressure is preferably ±10%.

According to the above-mentioned present invention, since evacuation of the source gas is performed by the purge by the inert gas, there is no need to provide a large diameter exhaust port, which is required for acquiring a high-vacuum, to the process chamber, thereby reducing the volume of the process chamber. Therefore, an amount of the source gas remaining in the process chamber can be reduced, which enables the evacuation being performed in a short time.

Moreover, since the pressure in the process chamber is always maintained constant by supplying also the purge gas when supplying the source gas, the thermal conductivity of the process gas in the process chamber is maintained constant. Therefore, heating of the substrate is uniform, which allows the surface temperature of the substrate to be maintained constant. Thus, an amount of adsorption of the source gas onto the surface of the substrate can be controlled, which achieves uniform processing.

Moreover, in the evacuation process when switching the source gas, the pressure in the process chamber is maintained nearly constant by using the inert gas purge and adjusting the amount of flow the inert gas, and, thereby, the supply of the source gases and the inert gas purge can be switched rapidly. That is, the time period for adjusting the pressure in the process chamber between the supply of the source gas and the inert gas purge becomes unnecessary, which can correspondingly reduce the total processing time.

Moreover, since the pressure inside the process chamber is a relatively high pressure, there is no influence given to the evacuation speed due to the source gas, which has been adsorbed on the inner wall of the process chamber, being released.

Other objects, features and advantages of the present invention will become more apparent from the following detailed description when read in conjunction with the accompanying drawings.

### BRIEF DESCRIPTION OF THE DRAWINGS

FIG. 1 is an illustrative structural diagram showing an entire structure of a processing apparatus according to a mode for carrying out the present invention; and

FIG. 2 is a time chart of a supply operation of source gases and purge gas in the processing apparatus shown in FIG. 1.

### BEST MODE FOR CARRYING OUT THE INVENTION

A description will now be given of a mode of carrying out the present invention.

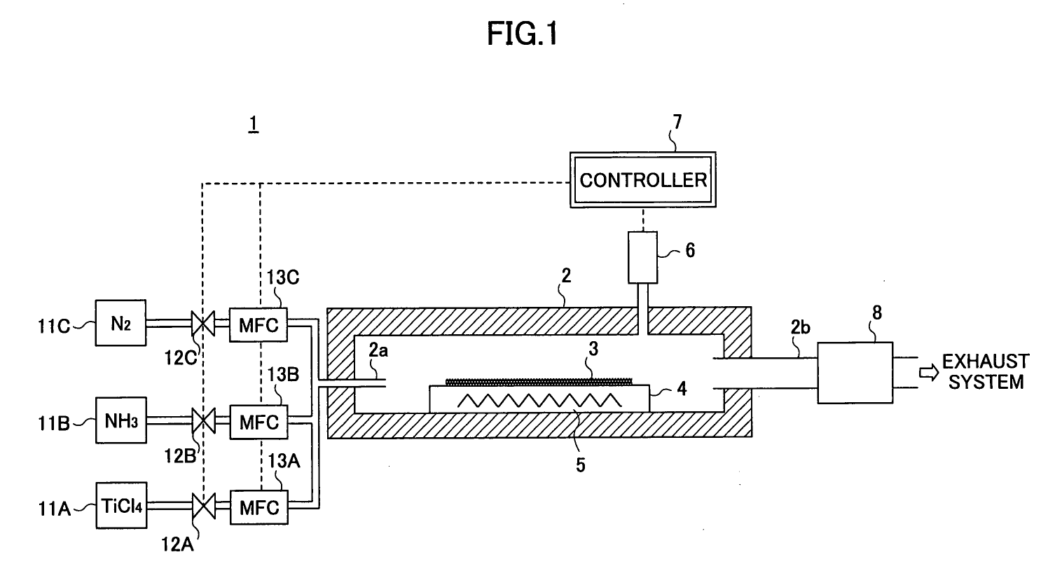

FIG. 1 is an illustrative structural diagram showing an entire structure of a processing apparatus according to a mode for carrying out the present invention. The processing apparatus 1 shown in FIG. 1 is a processing apparatus for forming a TiN film on a surface of a substrate to be processed by alternately supplying TiCl₄ and NH₃, as source gases, to the substrate to be processed under a reduced pressure. When supplying the source gasses to the substrate to be processed, the substrate to be processed is heated so as to promote a reaction of the source gases.

The processing apparatus 1 has a process chamber 2, and a susceptor 4 is arranged in the process chamber 2 as a placement stage on which a wafer 3 as the substrate to be processed is placed. The process chamber 2 is formed of a stainless steel, aluminum, etc., and a process space is formed therein. When the process chamber 2 is formed of aluminum, an anodizing process (alumite process) may be performed on a surface thereof.

The susceptor 4 incorporates an electric heater 5 such as tungsten so as to heat the wafer 3 placed on the susceptor 4 by heat of the electric heater 5. The susceptor 4 is formed of a ceramics material such as aluminum nitride (AlN) or alumina (Al₂O₃).

A pressure meter 6 such as a diaphragm vacuum gauge or the like is connected to the process chamber 2 so as to detect a pressure in the process chamber 2. A result of detection of the pressure meter 6 is sent to a controller 7 as an electric signal.

A supply port 2a is provided on a sidewall of the process chamber 2 so that the source gases and purge gas are supplied into the process chamber through the supply port 2a. Additionally, an exhaust port 2b is provided on a side opposite to the supply port 2a so that the source gases and purge gas in the process chamber 2 are evacuated through the exhaust port 2a. In the present embodiment, TiCl₄ and NH₃ are used as source gases, and N₂, which is an inert gas, is used as a purge gas. A supply line of TiCl₄, a supply line of NH₃ and a supply line of N₂ are connected to the supply port 2a of the process chamber. The source gases and the purge gas may be generically referred to as process gas.

The supply line of TiCl₄ as a source gas has a supply source 11A of TiCl₄, an open/close valve 12A and a mass-flow controller (MFC) 13A so that TiCl₄ from the supply source 11A of TiCl₄ is flow-controlled by the MFC 13A and supplied into the process chamber 2 through the supply port 2a. TiCl₄ flows into the supply port 2a through the MFC 13A by opening open/close valve 12A. Operations of the open/close valve 12A and the MFC 13A are controlled by the controller 7.

The supply line of NH₃ as a source gas has a supply source 11B of NH₃, an open/close valve 12B and a mass-flow controller (MFC) 13B so that NH₃ from the supply source 11B of NH₃ is flow-controlled by the MFC 13B and supplied into the process chamber 2 through the supply port 2a. NH₃ flows into the supply port 2a through the MFC 13B by opening open/close valve 12B. Operations of the open/close valve 12B and the MFC 13B are controlled by the controller 7.

The supply line of N₂ as a purge gas has a supply source 11C of N₂, an open/close valve 12C and a mass-flow controller (MFC) 13C so that N₂ from the supply source 11C of N₂ is flow-controlled by the MFC 13C and supplied into the process chamber 2 through the supply port 2a. N₂ flows into the supply port 2a through the MFC 13C by opening open/close valve 12C. Operations of the open/close valve 12C and the MFC 13C are controlled by the controller 7.

The processing apparatuses 1 according to the present embodiment has the above-mentioned structure, which forms a TiN film on the heated wafer 3 in the process chamber 2 by supplying alternately and repeatedly the source gases, TiCl₄ and NH₃, to the process chamber 2. When supplying the source gases, N₂ is supplied simultaneously as a purge gas to the process chamber 2.

The source gas and purge gas supplied to the process chamber 2 are evacuated through the exhaust port 2b. Here, in the present embodiment, when switching the supply of the source gas between TiCl₄ and NH₃, the purge of the source gas from the process chamber 2 is performed according to N₂ purge. Therefore, a dry pump 8 is connected to the exhaust port 2b as a vacuum pump for evacuation, and a turbomolecular pump as in a conventional case is not used. In the present embodiment, since the pressure in the process chamber 2 is continuously maintained at 200 Pa during processing of a substrate as mentioned later during processing of a substrate, the evacuation by the dry pump is sufficient.

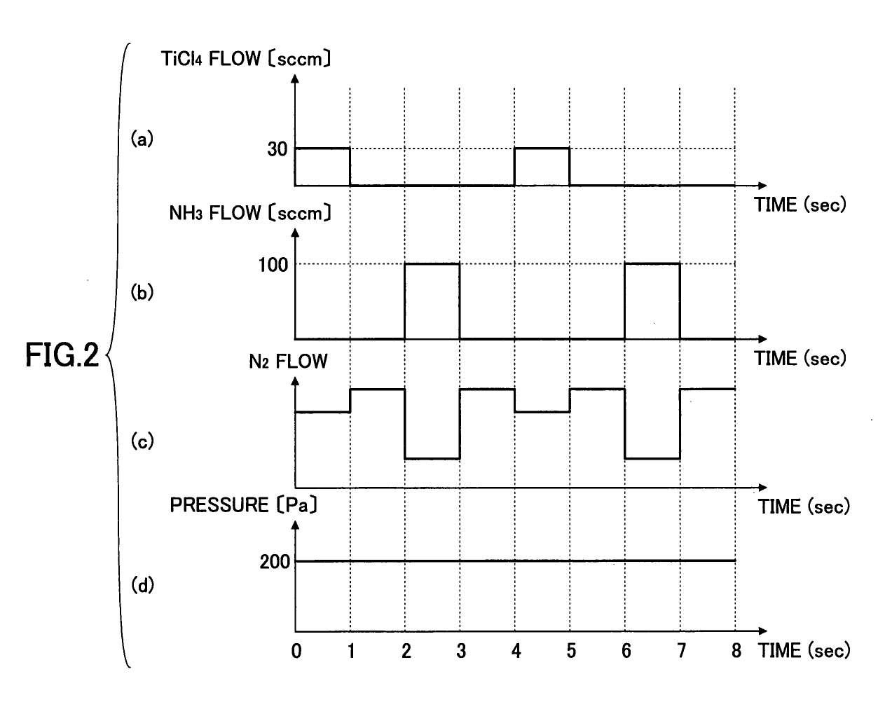

Here, a description will be given, with reference to FIG. 2, of a supply operation of the source gases and the pure gas in the processing apparatus. In FIG. 2, (a) shows an amount of flow of TiCl₄ supplied to the process chamber 2, (b) shows an amount of flow of NH₃ supplied to the process chamber 2, (c) shows an amount of flow of N₂ supplied to the process chamber 2, and (d) shows a pressure in the process chamber 2.

As shown in FIG. 2-(a) and (b), TiCl₄ and NH₃ as source gases are intermittently and alternately supplied to the process chamber 2. Only N₂ is supplied between the supply of TiCl₄, and the supply of NH₃ so that the purge of the source gas is performed. Moreover, in the present embodiment, an amount of flow of N₂ is controlled so that a pressure in the process chamber 2 is always constant during the processing of the wafer 3. That is, in the present embodiment, N₂ is supplied also during the period when TiCl₄ and NH₃ are supplied for pressure control.

An amount of flow when supplying TiCl₄ is 30 sccm, and an amount of flow when supplying NH₃ is 100 sccm. Here, an amount of N₂ is controlled to complement the amounts of flow of TiCL₄ and NH₃ as shown in FIG. 2-(c), thereby maintaining the pressure in the process chamber 2 always constant.

More specifically, as a source gas, TiCl₄ of 30 sccm is supplied to process chamber 2 for one second. In this reguard, N₂ is supplied into the process chamber 2 by a certain amount of flow so as to maintain the pressure in the process chamber 2 at 200 Pa. Then, the supply of TiCl₄ is stopped, and only N₂ is supplied to the process chamber 2 for one second so as to purge TiCl₄ in the process chamber 2 by N₂. Also in the N₂ purge, an amount of flow of N₂ is controlled so that the pressure in the process chamber 2 is 200 Pa. The control of the amount of flow of N₂ is achieved by detecting the pressure in the process chamber 2 by the pressure meter 6 and feeding back a result of the detection to the mass-flow controller 13C of the N₂ supply line.

Thereafter, NH₃ as a source gas of 100 sccm is supplied to the process chamber 2 for one second. In this regard, the pressure in the process chamber 2 is maintained at 200 Pa by supplying N₂ into the process chamber 2 by a certain amount of flow. Then, the supply of NH₃ is stopped and only N₂ is supplied to the process chamber 2 for one second so as to purge NH₃ in the process chamber 2 by N₂. The N₂ purge at this time is also performed by controlling the amount of flow of N₂ so that the pressure in the process chamber 2 is set to 200 Pa. The control of the amount of flow of N₂ is achieved by detecting the pressure in the process chamber 2 by the pressure meter 6 and feeding back a result of the detection to the mass-flow controller 13C of the N₂ supply line.

By repeating the above-mentioned cycle, a TiN film is formed on the wafer 3 heated at about 400° C. By complementing the amounts of flow of TiCl₄ and NH₃ with N₂, the inside of the process chamber 2 can always be maintained at 200 Pa. Here, an allowable range of pressure fluctuation in the process chamber 2 is preferably ±10% in consideration of fluctuation in uniformity of processing and thermal conductivity.

According to the above-mentioned embodiment, since evacuation of the source gases is performed not by a vacuum exhaust but by the N₂ purge, there is no need to provide an exhaust port of a large diameter so as to acquire a high-vacuum, and a volume of the process chamber 2 can be reduced. Therefore, the amount of the source gases (TiCl₄, NH₃) remaining in the process chamber 2 can be reduced, and the evacuation can be completed in a short period of time.

Moreover, since the pressure in the process chamber 2 is always maintained constant by supplying also the purge gas (N₂) when supplying the source gases (TiCl₄, NH₃), the thermal conductivity of the gas between the susceptor 4 and the wafer 3 is maintained constant. Therefore, heating of the wafer 3 is uniform, which allows the surface temperature of the wafer 3 to be maintained constant. Thus, an amount of adsorption of the source gases (TiCl₄, NH₃) onto the surface of the wafer 3 can be controlled, which achieves uniform processing.

Moreover, in the evacuation process when switching the source gases, the pressure in the process chamber 2 is maintained nearly constant by using the N₂ purge and adjusting the amount of flow of N₂, and, thereby, the supply of the source gases and the N₂ purge can be switched rapidly. That is, the time period for adjusting the pressure in the process chamber between the supply of the source gases and the N₂ purge becomes unnecessary, which can correspondingly reduce the total processing time. When supplying repeatedly and alternately a plurality of source gases, reducing the time spent on the pressure adjustment is particularly important.

Moreover, since the pressure inside the process chamber 2 is 200 Pa, which is a relatively high pressure, there is no influence given to the evacuation speed due to the source gases, which have been adsorbed on the inner wall of the process chamber 2, being released.

It should be noted that although N₂ is used as the purge gas in the above-mentioned embodiment, an inert gas such as Ar, He, etc., may also be used.

Moreover, although the TiN film is produced by TiCl₄ and NH₃ in the above-mentioned embodiment, using the processing apparatus 1 according to the present embodiment allows efficient execution of a film production process such as, as other examples, production of a TiN film by TiF₄ and NH₃, production of a TiN film by TiBr₄ and NH₃, production of a TiN film by TiI₄ and NH₃, production of a TiN film by Ti [N(C₂H₅CH₃)]₄ and NH₃, production of a TiN film by Ti[N(CH₃)₂]₄ and NH₃, production of a TiN film by Ti[N(C₂H₅)₂]₄ and NH₃, production of a TaN film by TaF₅ and NH₃, production of a TaN film by TaCl₅ and NH₃, production of a TaN film by TaBr₅ and NH₃, production of a TaN film by TaI₅ and NH₃, production of a TaN film by Ta (NC₃(CH₃)) (N(C₂H₅)₂)₃ and NH₃, production of a WN film by WF₆ and NH₃, production of a Al₂O₃ film by Al(CH₃)₃ and H₂O, production of a Al₂O₃ film by Al(CH₃)₃ and H₂O₂, production of a ZrO₂ film by Zr(O-t(C₄H₄))₄ and H₂O, production of a ZrO₂ film by Zr(O-t(C₄H₄))₄ and H₂O₂, production of a TaO₅ film by Ta (OC₃H₅)₅ and H₂O, production of a Ta₂O₅ film by Ta (OC₂H₅)₅ and H₂O₂, production of a Ta₂O₅ film by Ta (OC₂H₅)₅ and O₂, etc.

Moreover, the processing method according to the above-mentioned embodiment is applicable to, other than a film production process, a thermal oxidation process, an annealing process, a plasma process such as etching or plasma CVD, a thermal CVD, an optical CVD of a substrate or the like.

As mentioned above, according to the present invention, a time for switching source gases can be reduced by reducing a time spent of evacuation of a source gas, and a temperature of a surface of a substrate during processing can be maintained constant by performing supply and evacuation of the source gas under a constant pressure.

The present invention is not limited to the specifically disclosed embodiments, and variations and modifications may be made without departing from the scope of the present invention.

1. A processing apparatus performing a process on a substrate while supplying a process gas including a source gas and an inert gas, comprising:
a process chamber in which the substrate is accommodated;
process gas supply means for supplying the process gas into the process chamber;
exhaust means;
pressure detecting means for detecting a pressure in said process chamber; and
control means for controlling an amount of flow of the process gas supplied to said process chamber based on a result of detection of the pressure detecting means.

2. The processing apparatus as claimed in claim 1, wherein said processing gas supply means includes source gas supply means for supplying a source gas and an inert gas supply means for supplying an inert gas, and said control means controls an amount of flow of the process gas to be supplied to said process chamber by controlling an amount of flow of the inert gas by controlling said inert gas supply means.

3. The processing apparatus as claimed in claim 2, wherein said source gas supply means supplies a plurality of kinds of source gases alternately to the process chamber, and said inert gas supply means continuously supplies the inert gas to the process chamber.

4. The processing apparatus as claimed in claim 1, wherein said control means controls the amount of flow of the process gas so that a pressure in said process chamber is substantially constant.

5. The processing apparatus as claimed in claim 4, wherein said control means controls the amount of flow of the process gas so that a pressure in said process chamber falls within a range of ±10% of a predetermined pressure.

6. A processing method of applying a process to a substrate while supplying a process gas including a source gas and an inert gas, comprising:
a first step of supplying a first source gas to a process chamber at a first predetermined amount of flow and simultaneously supplying an inert gas to the process chamber so as to maintain inside said process chamber at a predetermined process pressure;
a second step of stopping supply of the first source gas and continuously supplying only the inert gas so as to maintain inside said process chamber at said predetermined process pressure;
a third step of supplying a second source gas to said process chamber at a second predetermined amount of flow and simultaneously supplying the inert gas to the process chamber so as to maintain inside said process chamber at said predetermined process pressure; and
a fourth step of stopping supply of the second source gas and continuously supplying only the inert gas so as to maintain inside said process chamber at said predetermined process pressure,
wherein the process is applied to said substrate by repeatedly performing said first step to said fourth step.

7. The processing method as claimed in claim 6, wherein said first source gas is TiCl₄, said second source gas is NH₃ and said inert gas is N₂.

8. The processing method as claimed in claim 7, wherein said first predetermined amount of flow is 1 to 50 sccm, said second predetermined amount of flow is 10 to 1000 sccm and said predetermined process pressure is 1 to 400 Pa.

9. The processing method as claimed in claim 8, wherein an allowable range of fluctuation of said predetermined process pressure is ±10%.
